(19) United States
(12) Patent Application Publication
(10) Pub. No.: US 2008/0157865 A1
(43) Pub. Date: Jul. 3, 2008

(54) TUNABLE CAPACITANCE MULTIPLIER CIRCUIT

(76) Inventors: Joe M. Smith, Scottsdale, AZ (US); Gary P. English, Chandler, AZ (US); Thomas R. Harrington, Margate, FL (US)

Correspondence Address: SMITH FROHWEIN TEMPEL GREENLEE BLAHA LLC, TWO RAVINIA DRIVE, SUITE 700, ATLANTA, GA, 30346, US

(21) Appl. No.: 11/617,813

(22) Filed: Dec. 29, 2006

(51) Int. Cl. H03L 7/08; H03H 11/40

(52) U.S. Cl. 327/553; 327/524

(57) ABSTRACT

An integrated circuit including a tunable capacitance multiplier. The integrated circuit includes a reference capacitor and a current source arrangement coupled in parallel to the reference capacitor. The current source arrangement can include a plurality of current sources that are switchably coupled to the reference capacitor in a manner that causes the capacitance of the reference capacitor to vary based on which current sources are coupled thereto. The current sources can be current mirror arrangements of other suitable current sources. The gain factors of the current sources are configured to establish the capacitance variability range and the incremental variance steps therein. In phase-locked loop (PLL) applications, the tunable capacitance multiplier is used to replace the main loop filter capacitor to provide a variable loop bandwidth, thus allowing relatively large values of capacitance to be realized using a relatively small physical capacitor.

### BACKGROUND OF THE INVENTION

1. Field of the Invention

The invention relates to capacitance multiplier circuits. More particularly, the invention relates to tunable capacitance multiplier circuits.

2. Description of the Related Art

A phase-locked loop (PLL) is a circuit that generates a periodic output signal, or clock, that has a constant phase relationship with a periodic input signal. PLLs are closed loop frequency control systems whose operation depends on the detection of the phase difference between the input and output signals of the circuit, and which are used in many types of measurement, microprocessor and communication applications. Often, PLLs are used to generate clocks, or to recover clocks from received data in such applications.

Typically, a conventional PLL includes a phase/frequency detector (PFD), a charge pump, a loop filter, a voltage-controlled oscillator (VCO) to generate the PLL output clock, and a frequency divider. The PFD measures the difference in phase between an input clock and a feedback clock, which may be the PLL output clock itself, or a clock generated by passing the PLL output clock through the frequency divider, and generates an error signal that is proportional to the measured phase difference. The charge pump generates an amount of charge that is proportional to the error signal and inputs the charge to the loop filter. The loop filter outputs a VCO control voltage that is supplied to the VCO. The frequency of the PLL output clock generated by the VCO is controlled by the loop filter (VCO control) voltage supplied to the VCO.

In a PLL circuit, there are many applications where the loop bandwidth should be variable or changeable. Loop bandwidth is a characteristic of a PLL that limits the spectral response of a PLL. More specifically, loop bandwidth is the cutoff frequency in the frequency response of a PLL loop operation, indicating how fast the PLL loop response is.

One example in which the loop bandwidth should be variable is when a relatively wide loop bandwidth is needed for initial frequency acquisition (to reduce acquisition time) but a relatively narrow loop bandwidth is needed to achieve optimum noise performance after acquisition. Another example is a loop that tracks two or more signals having different spectral bandwidths. In this case, more than one PLL loop bandwidth may be required to optimize noise performance. In another example, it may be desirable to improve phase noise in one mode of operation and improve residual frequency modulation (FM) in a different mode of operation. Such improvements typically would need the loop bandwidth to be variable.

Conventionally, the loop bandwidth is set primarily by a single dominate capacitor that is part of the PLL loop filter. Conventional methods to change loop filter bandwidth include changing the phase detector charge pump current or changing the gain of the loop filter. In many cases, the use of a tunable capacitance multiplier circuit will address the issues described above. For example, a tunable capacitance multiplier circuit could replace the main loop filter capacitor with a variable capacitance, which in turn, could vary the loop bandwidth.

A capacitance multiplier circuit typically is a transistor or transistor circuit that is configured to multiply the value of a capacitor coupled to the base of the transistor by an amount equal to the transistor's gain, also known as beta (β). Conventionally, fixed (non-adjustable) capacitance multiplier circuits have been used in PLL applications.

One advantage of using a tunable capacitance multiplier circuit for the purpose of varying the PLL loop bandwidth is that relatively large values of capacitance can be realized using a relatively small physical capacitor. Capacitor value reduction of greater than ten times is not unreasonable. The ability to reduce the capacitor value is particularly important in integrated circuit applications where maximum on-chip capacitance values of 10 picofarads (pF) or less may require the use of a multiplier if the loop filter is to be included on the integrated circuit chip. Also, the ability to reduce the capacitor value can be important in very narrow-band loops where the loop capacitor value may be too large to be realized with a passive capacitor.

### BRIEF DESCRIPTION OF THE DRAWINGS

FIG. 1 is a schematic diagram of a conventional capacitance multiplier circuit;

FIG. 2 is a schematic diagram of an equivalent circuit for the conventional capacitance multiplier circuit of FIG. 1;

FIG. 3 is a schematic diagram of a tunable capacitance multiplier circuit according to embodiments of the invention;

FIG. 4 is a schematic diagram of a conventional passive loop filter;

FIG. 5 is a schematic diagram of a variable loop bandwidth filter including a tunable multiplier circuit according to embodiments of the invention; and

FIG. 6 is a schematic diagram of the variable loop bandwidth filter of FIG. 5, using a bipolar junction transistor (BJT) current multiplier arrangement.

### DETAILED DESCRIPTION

In the following description, like reference numerals indicate like components to enhance the understanding of the tunable capacitance multiplier circuits through the description of the drawings. Also, although specific features, configurations and arrangements are discussed hereinbelow, it should be understood that such specificity is for illustrative purposes only. A person skilled in the relevant art will recognize that other steps, configurations and arrangements are useful without departing from the spirit and scope of the invention.

The tunable capacitance multiplier circuits described herein involve the use of a network of multiple current sources to change or vary the capacitance value of the capacitance multiplier circuit. One or more of the current sources in the current source arrangement can be current mirrors or other suitable current sources. The tunable capacitance multiplier circuits are based on a current mirror design in which the capacitance value is adjustable. In PLL applications where the loop bandwidth is desired to be variable, the tunable capacitance multiplier circuit can replace the main loop filter capacitor to vary the loop bandwidth.

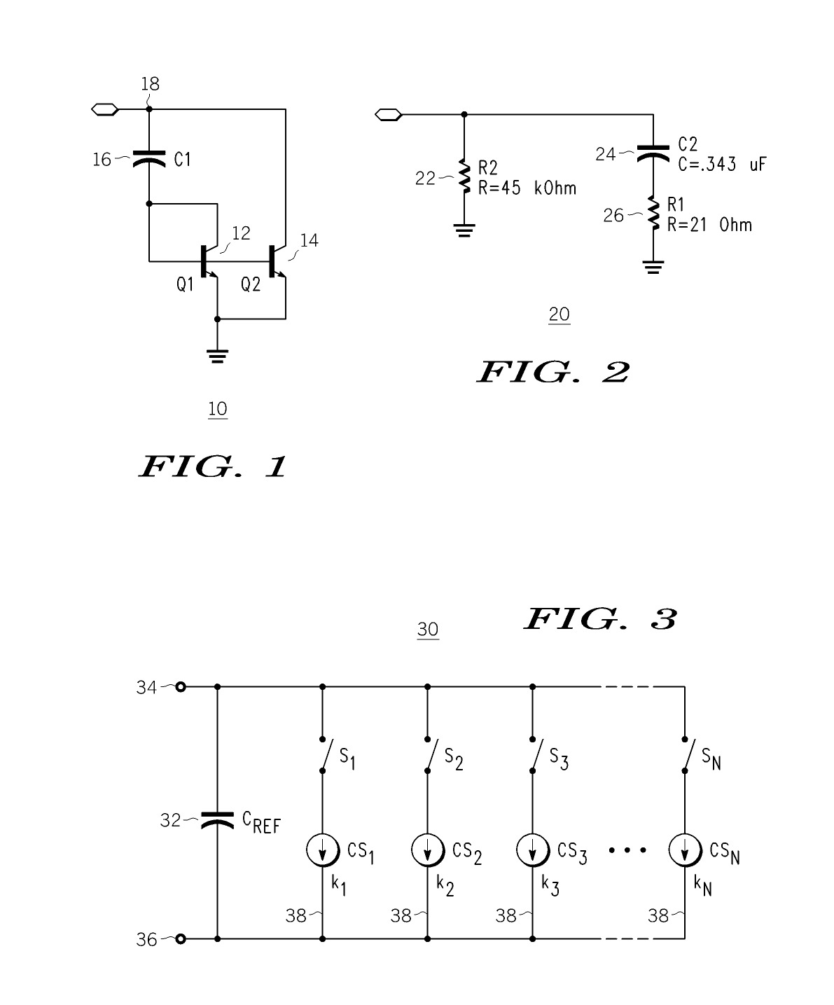

Referring now to FIG. 1, shown is a schematic diagram of a conventional capacitance multiplier circuit 10. The circuit 10 includes a first NPN transistor 12 (Q1) and a second NPN transistor 14 (Q2) coupled in a configuration that forms a current mirror. Alternatively, the current mirror can be formed by a single, multiple collector device rather than the separate, matched devices Q1 and Q2 shown. The transistor Q2 is scaled in area to be K times the area of the transistor Q1. A capacitor 16 (C1) is coupled to the transistors Q1 and Q2 as shown. The current through the capacitor C1, I_{C1}, also flows through the first transistor Q1. Thus, the current through the second transistor Q2, I_{C2}, is approximately K×I_{C1}. The impedance at a node 18 is primarily capacitive and has an effective capacitance of approximately C1×(1+K). It should be noted that the circuit 10 does not show a bias network for the transistors Q1 and Q2. The bias network supplies a current to transistors Q1 and Q2 such that the net current into the circuit 10 at the node 18 is close to zero.

Referring now to FIG. 2, with continuing reference to FIG. 1, shown is a schematic diagram of an equivalent circuit 20 for the conventional capacitance multiplier circuit 10 of FIG. 1. The equivalent circuit 20 includes a first branch, having a resistor 22 (R2), coupled in parallel to a second branch, having a capacitor 24 (C2) and a resistor 26 (R1) coupled in series. As an example, in the capacitance multiplier circuit 10 of FIG. 1, the capacitance of the capacitor C1 is 0.066 microfarads (μF) and the K=4, i.e., the area of the transistor Q2 is 4 times the area of the transistor Q1.

In the example, the current through the transistor Q1 (I_{C1}) is 250 microamps (μA) and the current through the transistor Q2 (I_{C2}) is K×I_{C1}, or 4×250 μA=1 milliamp (mA). The equivalent multiplier capacitance is C1×(1+K)=0.066 μF×(1+4)=0.343 μF. The series resistance of the capacitance multiplier is 21 ohms. The value of the series resistance of the capacitance multiplier changes with the current through the transistor Q1. For example, when the current through the transistor Q1 changes from 500 VA to 125 μA, the series resistance of the capacitance multiplier changes from 10 ohms to 40 ohms, respectively. Also, the series resistance will be dependent on the characteristics of the transistors Q1 and Q2, although the given values are representative of what may be achieved typically. As discussed previously herein, PLL applications and other applications that desire a relatively low series resistance (i.e., a relatively high Q capacitor) may be negatively affected by the non-ideal model of the conventional capacitance multiplier circuit in FIG. 1 and FIG. 2.

Referring now to FIG. 3, shown is a schematic diagram of a tunable capacitance multiplier circuit 30 according to embodiments of the invention. The tunable capacitance multiplier circuit 30 uses selective coupling of multiple current sources into the capacitance multiplier circuit to vary the overall capacitance value of the capacitance multiplier circuit. The tunable capacitance multiplier circuit 30 includes a reference capacitor 32 coupled between an input node 34 and an output node 36. The tunable capacitance multiplier circuit 30 also includes a plurality (N) of current source branches 38, also coupled between the input node 34 and the output node 36. As shown, the current source branches 38 are coupled in parallel to one another and coupled in parallel to the reference capacitor 32.

Each current source branch 38 includes a current source, CS_{N}, having a corresponding gain K_{N}. Each current source CS_{N} can be any suitable current source arrangement. For example, one or more of the current sources CS_{N} can be a current mirror arrangement using bipolar junction transistors or field effect transistors (FETs). Alternatively, one or more of the current sources CS_{N} can be an operational amplifier (op-amp)-based current mirror arrangement, or other suitable current source or current source arrangement.

Each current source CS_{N} is connected in series with a corresponding switch S_{N}. Although each switch S_{N} is shown as a physical switch, one or more of the switches S_{N} can be any suitable switching arrangement, including switching arrangements that do not actually include a physical switch. For example, one or more of the switches S_{N} can be a transistor switch.

In the manner shown, each current source CS_{N} is switchably coupled between the input node 34 and the output node 36. That is, when the switch S_{N} is closed, the corresponding current source CS_{N} in the branch is coupled in parallel to the reference capacitor 32. When the switch S_{N} is open, the corresponding current source CS_{N} in the branch is not coupled to the reference capacitor 32. Therefore, each of the N current sources CS_{N} can be selectively or switchably coupled to reference capacitor 32 depending on the state of its corresponding switch S_{N}.

The current source branches 38 are switchably coupled to the reference capacitor 32 in such a way that the capacitance (C_{MULTIPLIER}) of the tunable capacitance multiplier circuit 30, as measured across the input node 34 and the output node 36, is:

$${C}_{MULTIPLIER} = {C}_{REF} {\sum }_{i = 1}^{N} {s}_{i} {K}_{i}$$

where C_{REF} is the capacitance of the reference capacitor 32, Kᵢ is the gain of the corresponding current source CSᵢ relative to the current through the reference capacitor 32, and sᵢ is 1 if the switch Sᵢ is closed and 0 if the switch Sᵢ is open.

Depending on which current sources are switchably coupled to the reference capacitor 32, and depending on the gains K of the individual current sources, the capacitance of the multiplier circuit 30 can be controllably varied. For example, the values of the gain factors K for the individual current sources can be selected in a binary sequence. That is, K₁=1, K₂=2, K₃=4, K₄=8 and K_{N}=2^{N-1}. In such configuration, the capacitance of the multiplier circuit 30 would be variable between C_{REF} and 15C_{REF}, in equal steps of C_{REF}, depending on which current sources are coupled to the reference capacitor 32.

For example, with four current source branches having gains according to above binary weighting scheme, if only the first and second current sources (CS₁ and CS₂) are coupled to the reference capacitor 32, the capacitance of the multiplier circuit 30 is 3C_{REF}. (1C_{REF}+2C_{REF}). If only the first and third current sources (CS₁ and CS₃) are coupled to the reference capacitor 32, the capacitance of the multiplier circuit 30 is 5C_{REF}(1C_{REF}+4C_{REF}). If only the first, second and fourth current sources (CS₁, CS₂ and CS₄) are coupled to the reference capacitor 32, the capacitance of the multiplier circuit 30 is 11C_{REF} (1C_{REF}+2C_{REF}+8C_{REF}).

In another weighting scheme, the gains of the current sources are less than unity and decrease in a binary sequence. For example, K₁=½, K₂=¼, K₃=⅛ and K_{N}=½^{N}. In such configuration, with four current source branches having gains according to a less than unity binary weighting scheme, the capacitance of the multiplier circuit 30 would be variable between C_{REF} and 2C_{REF}, in equal steps having a resolution of C_{REF}/16. In yet another weighting scheme, the gains of the current sources are equal or approximately equal. In such configuration, with four current source branches having equal gains, the capacitance of the multiplier circuit 30 would be variable between C_{REF} and 4C_{REF}, in equal steps having a resolution of C_{REF}.

As discussed previously herein, the tunable capacitance multiplier circuit 30 can be used in a PLL to vary the PLL loop bandwidth. The tunable capacitance multiplier circuit 30 allows relatively large values of capacitance to be realized using a relatively small physical capacitor. In many applications, this allows both the loop filter and the multiplier circuit to be included on the same integrated circuit chip. Also, being able to reduce capacitor value is important in very narrow-band loops where the loop capacitor value may be too large to be realized with a passive capacitor.

Referring now to FIG. 4, shown is a schematic diagram of a conventional passive loop filter 40, e.g., for use in a PLL circuit that includes a phase/frequency detector and a charge pump. The loop filter 40 includes an input node 42, which typically is connected to the output of the charge pump (not shown) in the PLL, and an output node 44, which typically is connected to the input of the voltage-controller oscillator or VCO (not shown) in the PLL.

Typically, the loop filter 40 includes a first capacitor 46 (C1) connected in series with a parallel combination of a first or loop filter resistor 48 (R1) and a second capacitor 52 (C2), between the input node 42 and a point of reference potential, such as ground. Alternatively, although not shown, the loop filter can be a series combination resistor and capacitor, in parallel with a second capacitor, between the input node and ground. The loop filter also can include a second resistor 54 (R2) connected between the input node 42 and the output node 44, and a third capacitor 56 (C3) connected between the output node 44 and the point of reference potential.

In general, the phase/frequency detector generates an error signal, based on the difference between an input signal and a reference signal, and the charge pump generates an amount of charge proportional to the error signal. The loop filter accumulates the net charge from the charge pump and generates a loop filter voltage, which is input to the VCO as a control signal that biases the VCO. The VCO generates a periodic output signal, the frequency of which is a function of the loop filter voltage.

In a passive loop filter application, the first capacitor C1 creates a pole at close to zero frequency and is responsible for determining the gain of the loop filter. The loop bandwidth of the PLL is proportional to the square root of the gain of the loop filter, which is inversely proportional to the square root of the capacitance of the first capacitor C1. When using the passive loop filter, the loop bandwidth, ωₙ, is:

$${ω}_{n} = \sqrt{\frac{{K}_{Loop}}{{C}_{1}}}$$

where C₁ is the capacitance of the first capacitor C1 and K_{Loop} is the PLL open loop gain excluding the loop filter.

The value of the first resistor R1 is selected to provide a zero that determines the phase margin or stability of the loop filter. The capacitors C2, C3 and the resistor R2 work together to provide high frequency poles that filter sampling spurs and frequencies much higher than the loop bandwidth. In many applications, it is possible to eliminate the second resistor R2 and the third capacitor C3 from the loop filter.

Since the first capacitor C1 determines the loop gain and therefore the loop bandwidth, the first capacitor C1 is an ideal candidate to be replaced with a tunable capacitance multiplier circuit, such as the conventional tunable capacitance multiplier circuit shown in FIGS. 1 and 2 and described hereinabove. The substitution of the tunable capacitance multiplier circuit of FIG. 1 for the first capacitor C1 in the loop filter of FIG. 4 results in a loop filter that has an adjustable bandwidth. However, adjusting the loop bandwidth by changing the capacitance value of the first capacitor C1 also varies the phase margin and the loop stability. To maintain the same phase margin when decreasing the capacitance value of the first capacitor C1, the first resistor R1 must be increased such that:

$$\frac{R {1}_{bw 1}}{R {1}_{bw 2}} = \sqrt{\frac{C {1}_{bw 2}}{C {1}_{bw 1}}}$$

where R1_{bw1} and C1_{bw1} are the resistance and capacitance values, respectively, for the first loop bandwidth, and R1_{bw2} and C1_{bw2} are the resistance and capacitance values, respectively, for the second loop bandwidth. That is, the resistance of the first resistor R1 is inversely proportional to the square root of the capacitance of the first capacitor C1, if the phase margin stays the same. Also, the loop bandwidth is inversely proportional to the square root of the capacitance of the first capacitor C1. For the use of a tunable capacitance multiplier circuit in the loop filter 40 to be viable, a method for decreasing the resistance value of the first resistor R1 as the capacitance of the first capacitor C1 increases is needed. However, to maintain the same phase margin and to maintain loop stability, the product of the resistance of the resistor R1 times the square root of the capacitance of the capacitor C1 should be constant.

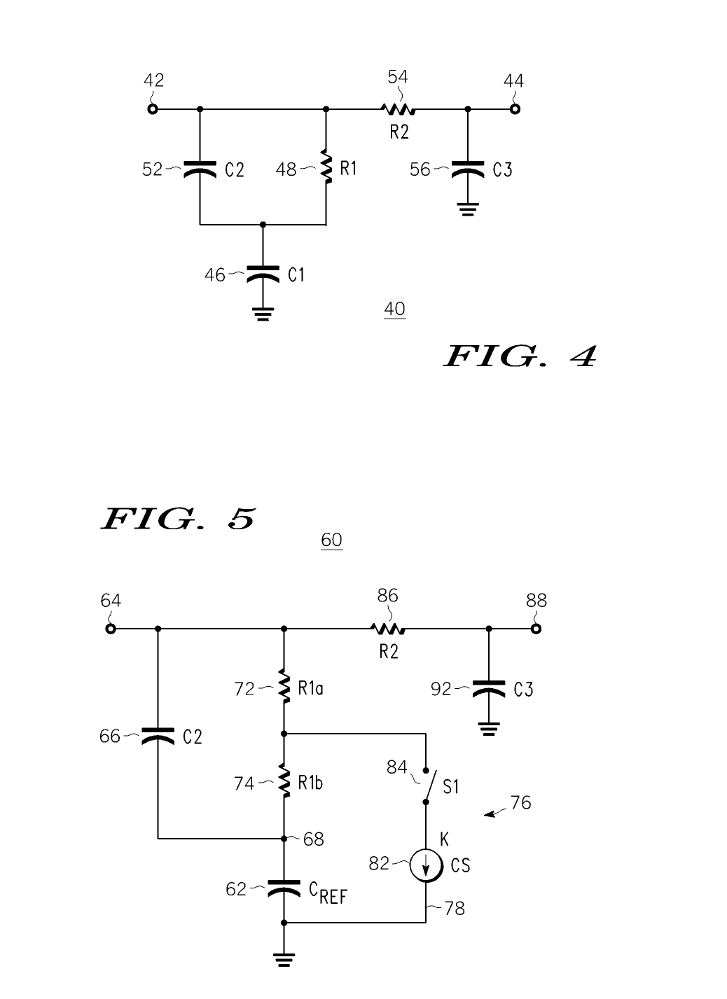

Referring now to FIG. 5, shown is a schematic diagram of a variable loop bandwidth filter 60, including a tunable multiplier circuit, according to embodiments of the invention. Similar to the conventional loop filter 40 shown in FIG. 4, the variable loop bandwidth filter 60 in FIG. 5 includes a first or reference capacitor 62 (C_{REF}) connected in series with a parallel resistor/capacitor combination between an input node 64 and a point of reference potential, such as ground. The parallel resistor/capacitor combination includes a second or loop filter capacitor 66 (C2) connected between the input node 64 and an intermediate node 68. However, in the variable loop bandwidth filter 60, the parallel resistor/capacitor combination includes a pair of resistors, i.e., a first loop filter resistor 72 (R1a) and a second loop filter resistor 74 (R1b) connected in series between the input node 64 and the intermediate node 68.

The variable loop bandwidth filter 60 also includes a tunable capacitance multiplier circuit 76, which, like the tunable capacitance multiplier circuit 30 shown in FIG. 3, includes one or more current source branches 78 (only one branch is shown). Each current source branch 78 includes a current source 82 (CS), having a corresponding gain K, and a switch 84 or switching arrangement for switchably coupling the current source branch 78 (and its current source 82) into the variable loop bandwidth filter 60. When the switch 84 is closed, the corresponding current source 82 is coupled in parallel across the reference capacitor 62 and the resistor second loop filter resistor 74 (R1b). The the phase margin stays constant regardless of whether the switch 84 (S1) is open or closed.

To choose the resistance values for the first loop filter resistor 72 (R1a) and the second loop filter resistor 74 (R1b) such that the loop phase margin remains constant whether the switch 84 (S1) is open or closed:

$$R 1 a = \frac{\sqrt{K} - 1}{K - 1} R 1$$

$$R 1 b = R 1 - R 1 a$$

where K is the gain factor of the current source 82 (CS), and R1 is the resistance value of the first resistor 48 (R1) in the loop filter circuit 40 in FIG. 3.

As discussed hereinabove, in the variable loop bandwidth filter 60 in FIG. 5, the tunable capacitance multiplier circuit 76 shows only one current source branch 78. However, it should be understood that the tunable capacitance multiplier circuit 76 can include multiple current sources, e.g., as shown in the tunable capacitance multiplier circuit 30 in FIG. 3. Furthermore, it should be understood that the inclusion of multiple current sources provides for multiple loop bandwidths.

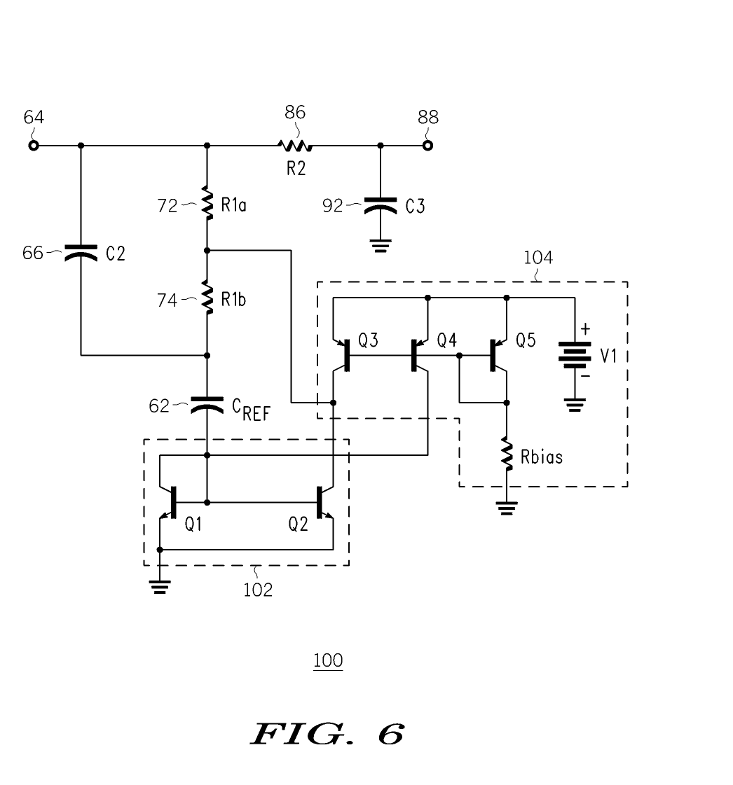

Referring now to FIG. 6, shown is a schematic diagram of a variable loop bandwidth filter of FIG. 5, using a bipolar junction transistor (BJT) current multiplier arrangement. Similar to the variable loop bandwidth filter 60 shown in FIG. 5, the variable loop bandwidth filter 100 in FIG. 6 includes the first or reference capacitor 62 (C_{REF}), the second capacitor 66 (C2), the first loop filter resistor 72 (R1a) and the second loop filter resistor 74 (R1b) connected between the input node 64, the output node 88 and variable loop bandwidth filter 60 also can include a second resistor 86 (R2) connected between the input node 64 and an output node 88, and a third capacitor 92 (C3) connected between the output node 88 and the point of reference potential.

In operation, the current source 82 senses the current through the reference capacitor 62 and multiplies that current by the current source gain factor K. Neglecting the second capacitor 66 (C2), when the switch 84 (S1) is closed, the impedance looking into the second loop filter resistor 74 (R1b) is made up of a capacitance (C_{REF}×K) in series with a resistance (R1b/K). It is possible to select the values of the loop filter resistors R1a and R1b whereby the product of the sum of the resistances of R1a and R1b(R1a+R1b) times the square root of capacitance C1 of the reference capacitor 62 should be constant whether the switch 84 (S1) is opened or closed.

As the switch 84 (S1) is closed, the capacitance changes from C_{REF} to K×C_{REF}. Therefore, assuming the poles from the second capacitor 66 (C2), the second resistor 86 (R2) and the third capacitor 92 (C3) are large relative to the maximum loop bandwidth for the filter circuit 60, the loop bandwidth, ωₙ, is:

$${ω}_{n} = \sqrt{\frac{{K}_{Loop}}{{C}_{1}}}$$

where C₁ is the capacitance of the reference capacitor 62 (C_{REF}) and K_{Loop} is the PLL open loop gain excluding the loop filter. When the switch 84 (S1) is open, C₁ is equal to C_{REF}; when the switch 84 (S1) is closed, C₁ is equal to C_{REF}×K. Furthermore, the point of reference potential in a manner similar to the variable loop bandwidth filter 60. The variable loop bandwidth filter 100 also can include the second resistor 86 (R2) and the third capacitor 92 (C3) connected similar to that in the variable loop bandwidth filter 60.

However, in the variable loop bandwidth filter 100 in FIG. 6, the tunable capacitance multiplier circuit is formed by a current mirror arrangement 102 and a bias network 104 for the current mirror arrangement 102. The current mirror arrangement 102 is formed by a first transistor Q1 and a second transistor Q2 connected as shown between the reference capacitor 62 and the point of reference potential. The areas of transistor Q1 and transistor Q2 are scaled in such a way that the current gain is K, i.e., the transistor Q2 is scaled in area to be K times the area of the transistor Q1. Also, although not shown, the transistor Q2 can be turned on or off by grounding the base of the transistor Q1, or by other suitable methods. Turning the transmission Q2 on or off causes a corresponding change in loop filter bandwidth as desired.

The bias network 104 includes a transistor Q3, a transistor Q4, a transistor Q5, a voltage source V1 and a bias resistor R_{bias} connected together as shown. The transistors Q3 and Q4 are scaled in the same ratio as the transistors Q1 and Q2, i.e., the transistor Q4 is scaled in area to be K times the area of the transistor Q3. The bias network 104 is connected to the current mirror 102 and across the second loop filter resistor 74 (R1b) and the reference capacitor 62, as shown. The resistance value of the bias resistor R_{bias} determines the current through the transistor Q3, the transistor Q4, the transistor Q1 and the transistor Q2.

The variable loop bandwidth filter 100 is for use in PLL applications with two loop bandwidths. However, using a variety of current scaling constants, the variable loop bandwidth filter 100 also can be used in PLL applications with multiple bandwidths.

Also, the inventive variable capacitance multiplier circuits shown and described hereinabove are not limited to phase locked loop applications. Other applications in which this type of variable capacitance multiplier circuit may be useful include tunable filter applications where discrete frequency changes are sought, and VCO applications where discrete frequency steps are sought. Also, although the transistors shown and described herein are shown as bipolar junction transistors (BJTs), it should be understood that one or more of the transistors can be field effect transistors (FETs).

It will be apparent to those skilled in the art that many changes and substitutions can be made to the tunable capacitance multiplier circuits herein described without departing from the spirit and scope of the invention as defined by the appended claims and their full scope of equivalents.

1. An integrated circuit including a tunable capacitance multiplier, comprising:
a reference capacitor coupled between a first node and a second node; and
a current source arrangement coupled between the first node and the second node in parallel to the reference capacitor,
wherein the current source arrangement includes a plurality of current sources switchably coupled between the first node and the second node in such a way that the capacitance of the reference capacitor varies based on which current sources are coupled between the first node and the second node.

2. The integrated circuit as recited in claim 1, wherein each of the current sources has a gain, and wherein the gains of the current sources are weighted using a binary weighting scheme.

3. The integrated circuit as recited in claim 2, wherein the current source arrangement includes N current sources, wherein each current source has a gain factor K, and wherein the gain factor K_{N}=2^{N-1}.

4. The integrated circuit as recited in claim 1, wherein the current source arrangement includes N current sources, wherein each current source has a gain factor K, and wherein the gain factor K_{N}=½^{N}.

5. The integrated circuit as recited in claim 1, wherein the reference capacitor has a capacitance C_{REF}, wherein each of the current sources has a gain, wherein the gains of the current sources are configured in such a way that the capacitance of the tunable capacitance multiplier varies as a multiple of the capacitance C_{REF}.

6. The integrated circuit as recited in claim 1, wherein each of the current sources has a gain, and wherein the gains of the current sources are approximately equal.

7. The integrated circuit as recited in claim 1, wherein at least one of the current sources in the current source arrangement is a current mirror.

8. An integrated circuit including a tunable capacitance multiplier, comprising:
a reference capacitor coupled between a first node and a second node; and
a plurality of combinations of a current source connected in series with a switch, wherein the combinations are connected in parallel, wherein the combinations are connected in parallel with the reference capacitor, and wherein the capacitance of the reference capacitor depends on which of the combination switches are closed to couple the corresponding combination current source in parallel with the reference capacitor.

9. The integrated circuit as recited in claim 8, wherein each of the current sources has a gain, and wherein the gains of the current sources are weighted using a binary weighting scheme.

10. The integrated circuit as recited in claim 9, wherein the current source arrangement includes N current sources, wherein each current source has a gain factor K, and wherein the gain factor K_{N}=2^{N-N}.

11. The integrated circuit as recited in claim 9, wherein the current source arrangement includes N current sources, wherein each current source has a gain factor K, and wherein the gain factor K_{N}=½^{N}.

12. The integrated circuit as recited in claim 8, wherein each of the combination current sources has a gain, and wherein the gains of the combination current sources are approximately equal.

13. The integrated circuit as recited in claim 8, wherein at least one of the current sources in the current source arrangement is a current mirror.

14. An integrated circuit including a phase-locked loop (PLL) loop filter circuit, comprising:
a loop filter capacitor coupled between a first node and a first intermediate node;
a reference capacitor coupled between the first intermediate node and a point of reference potential;
a first loop filter resistor coupled between the first node and a second intermediate node;
a second loop filter resistor coupled between the first intermediate node and the second intermediate node; and
a current source arrangement coupled between the second intermediate node and the point of reference potential,
wherein the current source arrangement includes a plurality of current sources switchably coupled between the second intermediate node the first node and the point of reference potential in such a way that the capacitance of the reference capacitor varies based on which current sources are coupled to the reference capacitor.

15. The integrated circuit as recited in claim 14, wherein the current source arrangement is coupled in parallel with the second loop filter resistor and the reference capacitor.

16. The integrated circuit as recited in claim 14, wherein the current source arrangement includes a plurality of combinations of a current source connected in series with a switch, wherein the combinations are connected in parallel, wherein the combinations are connected in parallel with the reference capacitor, and wherein the capacitance of the reference capacitor depends on which of the combination switches are closed to couple the corresponding combination current source in parallel with the reference capacitor.

17. The integrated circuit as recited in claim 14, wherein the current source arrangement includes a current mirror and a bias network connected to the current mirror in such a way that the bias network determines the current through the current mirror, which varies the capacitance of the reference capacitor.

18. The integrated circuit as recited in claim 14, wherein the first node is an input node, and wherein the integrated circuit further comprises a third loop filter resistor coupled between the input node and an output node, and a third loop filter capacitor coupled between the output node and the point of reference potential.
